(19) United States
(12) Patent Application Publication
(10) Pub. No.: US 2007/0146191 A1
(43) Pub. Date: Jun. 28, 2007

(54) Analog-to-digital converter

(75) Inventors: Shigeyasu Iwata, Ome-shi (JP); Takeshi Ueno, Kawasaki-shi (JP); Toshifumi Yamamoto, Tsukui-gun (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/585,077

(22) Filed: Oct. 24, 2006

(30) Foreign Application Priority Data
Dec. 22, 2005 (JP) 2005-369570

(51) Int. Cl. H03M 1/12

(52) U.S. Cl. 341/155

(57) ABSTRACT

An analog-to-digital converter includes a track hold circuit, a reference voltage generating circuit, a switched capacitor circuit, a preamplifier that amplifies a voltage held by the switched capacitor circuit, a comparator that generates a logic level corresponding to an output from the preamplifier, and an encoder that converts the logic level into a binary code (n-bit digital output). If capacitors constituting the switched capacitor circuit are charged and the charges in these capacitors then vary, each capacitor is recharged by an amount corresponding to the particular variation.

### CROSS-REFERENCE TO RELATED APPLICATIONS

This application is based upon and claims the benefit of priority from Japanese Patent Application No. 2005-369570, filed Dec. 22, 2005, the entire contents of which are incorporated herein by reference.

### BACKGROUND

1. Field

The invention relates to an analog-to-digital converter. In particular, the invention relates to a parallel analog-to-digital converter utilizing a switched capacitor.

2. Description of the Related Art

Growing demands have been made for analog-to-digital converters that digitize analog information. In particular, there is a pressing requirement to digitize broadband analog signals for digital TVs and DVD video recorders at high speeds. A parallel analog-to-digital converter is a high-speed analog-to-digital converter that meets this requirement (Jpn. Pat. Appln. KOKAI Publication No. 2003-218697). Other known conventional techniques for high-speed analog-to-digital converters include an analog-to-digital converter realizing 1.3 Gsample/s (Michael Choi et al., “A 6-b 1.3-Gsample/s A/D Converter in 0.35-μm CMOS”, IEEE JOURNAL OF SOLID-STATE CIRCUITS, VOL. 36, NO. 12, DECEMBER 2001 [pp. 1847-1858] and an analog-to-digital converter realizing 200 Msample/s (Declan Dalton et al., “A 200-MSPS 6-Bit Flash ADC in 0.6-μm CMOS”, IEEE TRANSACTIONS ON CIRCUITS AND SYSTEMS-II: ANALOG AND DIGITAL SIGNAL PROCESSING, VOL. 45, NO. 11, NOVEMBER 1998 [pp. 1433-1444]).

With the analog-to-digital converter in Jpn. Pat. Appln. KOKAI Publication No. 2003-218697, when a control clock CLK is high, first and second preamplifiers are both reset. When a sample-and-hold circuit holds a sampled value, the control clock CLK goes a low. The first preamplifier then enters an amplifying mode to start an amplifying operation. The second preamplifier changes from an offset compression mode to an amplification mode to increase gain.

With the analog-to-digital converter in Michael Choi et al., a track hold (T/H) circuit located at the head of the entire circuit serves to increase the speed of the converter as shown in FIG. 2. With such a parallel analog-to-digital converter as shown in FIG. 2, the reduced scale of a CMOS process leads to a decrease in the breakdown voltage of transistors and thus in power supply voltage. Thus, a reduction in voltage and power consumption is essential for such analog-to-digital converters.

In Declan Dalton et al., FIG. 2 shows the block configuration of the analog-to-digital converter in this document. FIG. 6 shows the circuit configuration of a comparator as well as a timing chart. Input circuitry in FIG. 2 of this document is composed of a source follower with a strong driving force. FIG. 6 of the document shows that when AZ2 and AZ3 are high (switch on), a sampling capacitance (Cs) is charged with “a reference voltage (Ref)—the common mode voltage of a comparator output (Out)”. When AZ1 goes high (switch on), a differential input to the comparator is equal to “an input voltage (In)—the reference voltage (Ref)”.

An object of the invention is to obtain an A/D converter that can operate at high speeds.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a diagram illustrating the configuration of a parallel A/D converter according to a first embodiment of the invention;

FIGS. 2A, 2B, 2C, 2D, 2E and 2F are timing charts, each of which illustrates the mutual relationship between signals obtained from a timing generating circuit for the A/D converter shown in FIG. 1;

FIG. 3 is a circuit diagram illustrating a specific example of a timing generating circuit for the A/D converter shown in FIG. 1;

FIG. 4 is a circuit diagram illustrating a specific example of a switched capacitor circuit and a preamplifier for the A/D converter shown in FIG. 1; and

FIG. 5 is a diagram illustrating the configuration of a parallel A/D converter according to a second embodiment of the invention.

### DETAILED DESCRIPTION

Various embodiments according to the invention will be described hereinafter with reference to the accompanying drawings. In general, according to one embodiment of the invention, an analog-to-digital converter comprises a track hold circuit which follows a variation in analog input value and which holds the analog input value at a predetermined timing, the track hold circuit outputting the analog input hold value,

a reference value generating circuit which generate predetermined reference values, a switched capacitor circuit including a switch circuit which is switched on and off at a predetermined timing and a capacitor circuit which is charged at the predetermined timing under a first voltage corresponding to the predetermined reference values, the switched capacitor circuit holding a second voltage corresponding to a difference between the predetermined reference values or the first voltage and the analog input hold value,

a preamplifier which amplifies the second voltage held by the switched capacitance circuit to provide a preamplifier output and which has an input capacitance smaller than the capacity of the capacitor circuit, a comparator which generates a logic level corresponding to the preamplifier output and an encoder which converts the logic level generated by the comparator into a binary code corresponding to the analog input value.

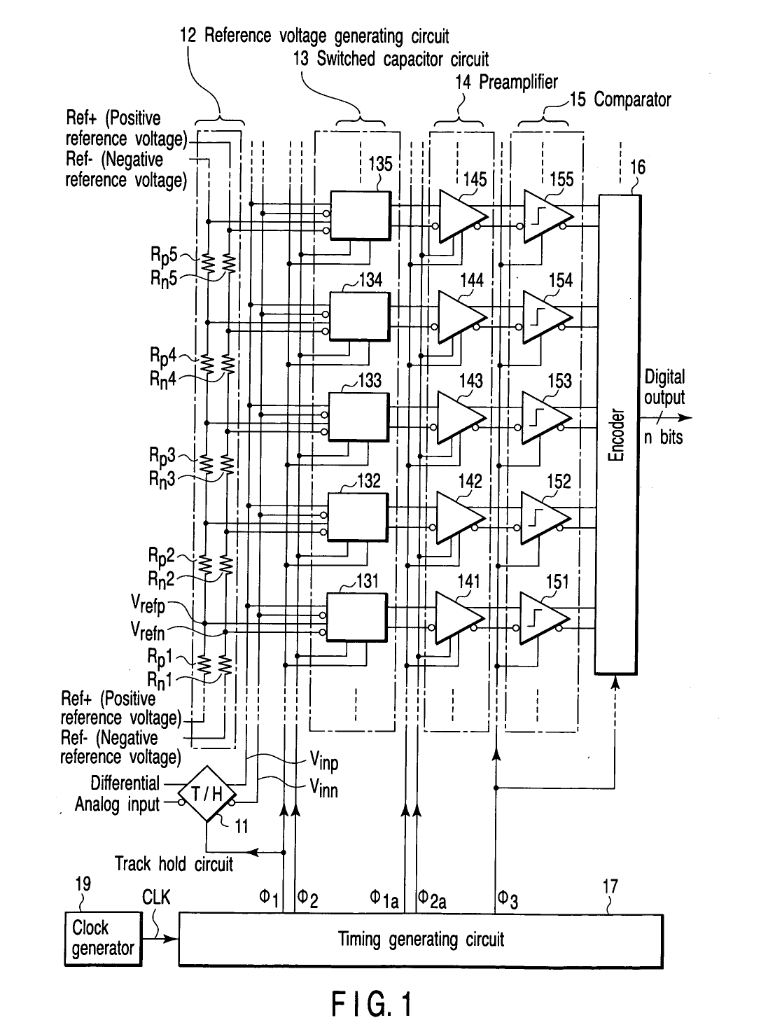

FIG. 1 is a diagram illustrating the configuration of a parallel A/D converter according to a first embodiment of the invention. The A/D converter is a circuit that samples and converts a differential analog input in synchronism with a clock CLK and converts the input into an n-bit digital output. The A/D converter is composed of a track hold circuit 11, a reference voltage generating circuit 12, a switched capacitor circuit 13, a preamplifier 14 that amplifies a voltage held by the switched capacitor circuit 13, a comparator 15 that generates a logic level corresponding to an output from the preamplifier 14, and an encoder 16 that converts the logic level into a binary code (n-bit digital output).

The track hold circuit 11 follows a variation in analog input value, holds an analog input value at a predetermined timing, and outputs analog input hold values (Vinp, Vinn). The track hold circuit 11 is configured to output, as the analog input hold values (Vinp, Vinn), a positive analog input hold value (Vinp) and a negative analog input hold value (Vinn) both corresponding to the analog input value.

The reference voltage generating circuit (reference value generating circuit) 12 generates predetermined reference values (Vrefp, Vrefn). The reference voltage generating circuit 12 is configured to generate a positive reference value (Vrefp) and a negative reference value (Vrefn) as the predetermined reference values (Vrefp, Vrefn).

The switched capacitor circuit 13 includes switch circuits (SW1 to SW4) that are switched on and off at predetermined timings (φ1, φ2) and capacitor circuits (Cs1, Cs2) that are charged at the predetermined timings (φ1, φ2) under first voltages (Vrefp−Vcm, Vrefn−Vcm) corresponding to the predetermined reference values (Vrefp, Vrefn). The switched capacitor circuit 13 holds a second voltage ([Vinp−Vinn]−[Vrefp−Vrefn]) corresponding to the difference between the predetermined reference values (Vrefp, Vrefn) or first voltages (Vrefp−Vcm, Vrefn−Vcm) and the analog input hold values (Vinp, Vinn). The switched capacitor circuit 13 is configured to hold, as the second voltage, a third voltage ([Vinp−Vinn]−[Vrefp−Vrefn]) between the first difference (Vinp−Vinn) between the positive analog input hold value (Vinp) and the negative analog input hold value (Vinn) and the second difference (Vrefp−Vrefn) between the positive reference value (Vrefp) and the negative reference value (Vrefn).

The preamplifier 14 has an input capacitance smaller than that of the capacitor circuits (Cs1, Cs2). The preamplifier 14 amplifies the second voltage ([Vinp−Vinn]−[Vrefp−Vrefn]) held by the switched capacitor circuit 13 to provide preamplifier outputs (Voutp, Voutn). The preamplifier 14 is a differential amplifier circuit that amplifies the third difference ([Vinp−Vinn]−[Vrefp−Vrefn]) to provide the preamplifier outputs (Voutp, Voutn), that is, the positive preamplifier output (Voutp) and the negative preamplifier output (Voutn).

The comparator 15 generates a logic level corresponding to the preamplifier outputs (Voutp, Voutn). The comparator 15 is configured to generate the logic level on the basis of a numerical comparison of the positive preamplifier output (Voutp) with the negative preamplifier output (Voutn).

The encoder 16 converts the logic level generated by the comparator 15 into a binary code (n-bit digital output) corresponding to the analog input value.

The A/D converter in FIG. 1 is provided with plural sets (131 to 135+141 to 145+151 to 155; FIG. 1 shows only five sets by way of example) of combinations (13+14+15) of the switched capacitor circuit 13, preamplifier 14, and comparator 15. The reference voltage generating circuit 12 is configured to generate different reference values (obtained by dividing Ref+ to Ref− into Rp1 to Rp5 and Rn1 to Rn5) the number of which corresponds to the number of the above plural sets (for example, five sets).

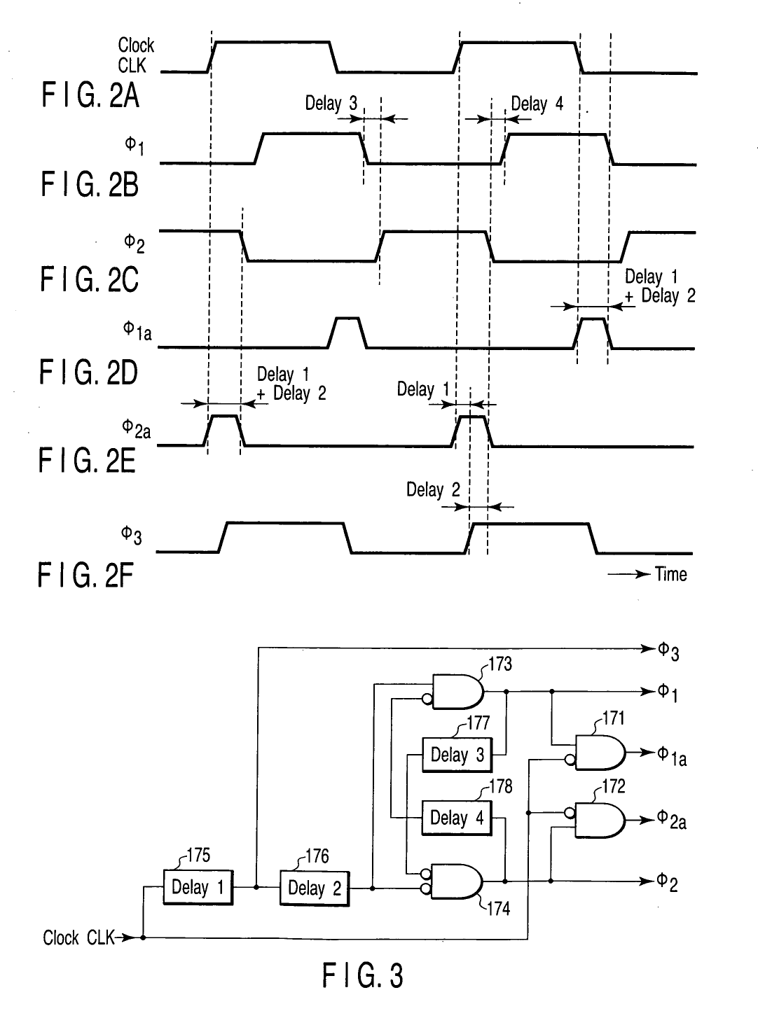

Each of FIGS. 2A, 2B, 2C, 2D, 2E and 2F is a timing chart illustrating the mutual relationship among signals obtained from the timing generating circuit 17, used in the A/D converter in FIG. 1. The timing generating circuit 17 (for details, see FIG. 3) uses an input clock CLK as a reference to output signals φ1, φ2, φ1a, φ2a, and φ3.

An output from the track hold circuit 11 in FIG. 1 tracks the differential analog input when φ1 is High. When φ1 becomes Low, the output holds an output value obtained immediately before φ1 becomes Low. The reference voltage generating circuit 12 uses reference voltage dividing circuits (Rp1 to Rp5, Rn1 to Rn5) to divide the voltage between a positive reference voltage Ref+ and a negative reference voltage Ref− into plural voltages. The resulting voltages are input to the switched capacitor circuit 13. The switched capacitor circuit 13 compares the reference signal with the differential analog signal output by the track hold circuit 11 (φ1a, φ2a, and the like will be described later).

FIG. 3 is a circuit diagram illustrating a specific example of the timing generating circuit 17 for the A/D converter shown in FIG. 1. With this A/D converter, if the charges in any charged capacitor constituting the switched capacitor circuit 13 vary, that capacitor is recharged by an amount corresponding to the variation. This requires the specially designed timing generating circuit 17.

The timing generating circuit 17 generates a first timing signal φ1 and a second timing signal φ2 which set the predetermined timings (φ1, φ2) with respect to the predetermined clock CLK. The first timing signal φ1 and second timing signal φ2 are illustrated in FIGS. 2B and 2C, respectively. The timing generating circuit 17 is further configured to generate a first pulse signal φ1a (see FIG. 2D) having a pulse width (delay 1+delay 2) of a predetermined duration starting from a rear signal edge of the predetermined clock CLK, and a second pulse signal φ2a (see FIG. 2E) having a pulse width (delay 1+delay 2) of the predetermined duration starting from a front signal edge of the predetermined clock CLK.

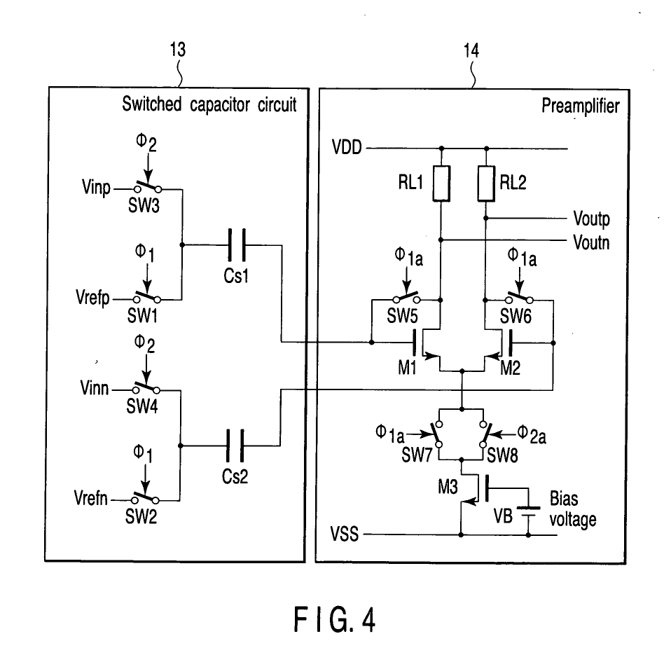

FIG. 4 is a circuit diagram illustrating a specific example of the switched capacitor circuit 13 and preamplifier 14 for the A/D converter shown in FIG. 1. The A/D converter in FIG. 1 uses the first analog input hold value Vinp and second analog input hold value Vinn as the analog input hold values (Vinp, Vinn), the first reference value Vrefp and second reference value Vrefn as the predetermined reference values (Vrefp, Vrefn), and the first preamplifier output Voutp and second preamplifier output Voutn as the preamplifier outputs (Voutp, Voutn).

The capacitor circuits (Cs1, Cs2) constituting the switched capacitor circuit 13 include the first capacitor Cs1 and the second capacitor Cs2. The switch circuit (SW1 to SW4) constituting the switched capacitor circuit 13 include the first switch SW1 that switches on and off the connection between one end of the first capacitor Cs1 and the first reference value Vrefp in accordance with the first timing signal φ1, the second switch SW2 that switches on and off the connection between one end of the second capacitor Cs2 and the second reference value Vrefn in accordance with the first timing signal φ1, the third switch SW3 that switches on and off the connection between one end of the first capacitor Cs1 and the first analog input hold value Vinp in accordance with the second timing signal φ2, and the fourth switch SW4 that switches on and off the connection between one end of the second capacitor Cs2 and the second analog input hold value Vinn in accordance with the second timing signal φ2.

The preamplifier 14 comprises a first transistor M1 having a gate connected to the other end of the first capacitor Cs1, a drain that provides the second preamplifier output Voutn, and a source, a second transistor M2 having a gate connected to the other end of the second capacitor Cs2, a drain that provides the first preamplifier output Voutp, and a source, and a current source (M3) selectively connected to the source of the first transistor M1 and the source of the second transistor M2. The current source (M3) can be composed of the third transistor M3 configured so as to pass a given drain current through itself under a predetermined bias voltage VB.

The preamplifier 14 further comprises a fifth switch SW5 that switches on and off the gate and drain of the first transistor M1 in accordance with the first pulse signal φ1a, a sixth switch SW6 that switches on and off the gate and drain of the second transistor M2 in accordance with the first pulse signal φ1a, a seventh switch SW7 that switches on and off the sources of the first and second transistors M1 and M2 and the current source (or the drain of the third transistor M3) in accordance with the first pulse signal φ1a, and an eighth switch SW8 that switches on and off the sources of the first and second transistors M1 and M2 and the current source (or the drain of the third transistor M3) in accordance with the second pulse signal φ2a.

If the charges in the capacitor circuits (Cs1, Cs2) charged by the first voltages (Vrefp−Vcm, Vrefn−Vcm) vary as a result of charge injection or clock feed-through, the seventh switch SW7 is turned on to recharge the capacitor circuits (Cs1, Cs2) by an amount corresponding to the variation (during a limited duration corresponding to the delay 1+delay 2). The timing generating circuit 17 is configured to generate and provide a pulse signal φ1a for the switched capacitor circuit 13 and preamplifier 14 so that the capacitor circuits are timely recharged by the amount corresponding to the variation.

Vrefp and Vrefn are output signals from the reference voltage generating circuit 12. Vinp and Vinn are output signals from the track hold circuit 11. To allow the switched capacitor circuit 13 to operate correctly, turning-on of the switches SW1 and SW2 in response to φ1 must not be simultaneous with turning-on of the switches SW3 and SW4 in response to φ1. The amount of non-overlapping between φ1 and φ2 required to prevent simultaneous turn-on is set on the basis of a delay 3 and a delay 4 shown in FIG. 3.

When φ1 becomes High, the switches SW1 and SW2 are turned on. Subsequently, when φ1a becomes “High”, the switches SW5, SW6, and SW7 are turned on to start passing a current through the amplifier 14. The I/O level of the preamplifier 14 is set to the common mode level Vcm of preamplifier outputs. Consequently, the sampling capacitance Cs1 is charged with Cs1×(Vrefp−Vcm). The sampling capacitance Cs2 is charged with Cs2×(Vrefn−Vcm). Then, the minimum time required to charge the sampling capacitance Cs1 and Cs2 is set equal to the pulse width of φ1a, which can be set on the basis of the delay 1+delay 2 in FIG. 3.

When φ1a is High, Vrefp, Vrefn, and Vcm are fixed. Consequently, after the sampling capacitance Cs1 and Cs2 are charged, the amount of charges is always constant. However, the amount of charges actually varies slightly as a result of charge injection or clock feed-through in the switches (electronic switches utilizing the conduction and non-conduction between the drain and source of MOS transistors). In this case, the capacitance are recharged by an amount corresponding to the variation caused by the charge injection or clock feed-through, on the basis of the delay 1+delay 2. The capacitance have only to be recharged by only a small amount. Consequently, the recharging is quickly completed. This enables faster operations.

While φ1a is High, the preamplifier 14 is subjected to a feedback operation (turning on the switches SW5 and SW6 causes 100% feedback from the drain to gate of each of the transistors M1 and M2). This enables offset canceling. When the offset voltage in input equivalent for the preamplifier 14 is defined as Vos, the offset voltage in input equivalent Vos can be reduced to 1/(1+A0) where A0 denotes the gain of the differential amplifying circuit consisting of the differential transistors M1 and M2 and loads RL1 and RL2.

When φ2 becomes high, the switches SW3 and SW4 are turned on. On this occasion, the output from the track hold circuit 11 remains held. Consequently, the differential input to the preamplifier 14 is held at (Vinp−Vinn)−(Vrefp−Vrefn). When φ2a is subsequently becomes High, the switching SW8 is turned on to allow the preamplifier 14 to amplify the differential input. Once the preamplifier 14 amplifies the differential input, the comparator 15 numerically compares a differential output Voutp−Voutn from the preamplifier 14 with a certain value at the rise of φ3 and then significantly amplifies it to a logic level. The encoder 16 converts the output from the comparator 15 into a binary code and then outputs the binary code. The minimum time required to amplify the differential input is set on the basis of the delay 1 shown in FIG. 3.

In short, the sampling capacities Cs1 and Cs2 are recharged by the amount corresponding to a charge variation, in accordance with φ1a. The duration of φ1a is set on the basis of the delay 1+delay 2. During the duration of φ2a, the differential input to the preamplifier 14 is amplified. The duration is set on the basis of the delay 1. With the circuit configuration shown in FIGS. 1 and 3, after the delay 1 following the rise of φ2a (that is, after the preamplifier 14 completes amplification), the clock φ3 for the comparator 15 rises to further amplify the output from the preamplifier 14 to a logic level.

During a hold period, the sampling capacitance Cs2 and the input capacitance of the preamplifier 14 are connected in series with a load on the track hold circuit 11. The input capacitance (for example, several pF or less) of the preamplifier 14 can be made sufficiently smaller than the sampling capacitance Cs2 (for example, several tens of pF or more). Consequently, the capacitance load of the track hold circuit 11 is substantially determined by the input capacitance of the preamplifier 14. This enables the track hold circuit 11 to operate only on a light capacitance load and thus at an increased speed. Further, the differential input to the preamplifier 14 is held at (Vinp−Vinn)−(Vrefp−Vrefn). This substantially prevents the accuracy of the A/D converter from being affected by a possible skew in φ3 supplied to each comparator (16).

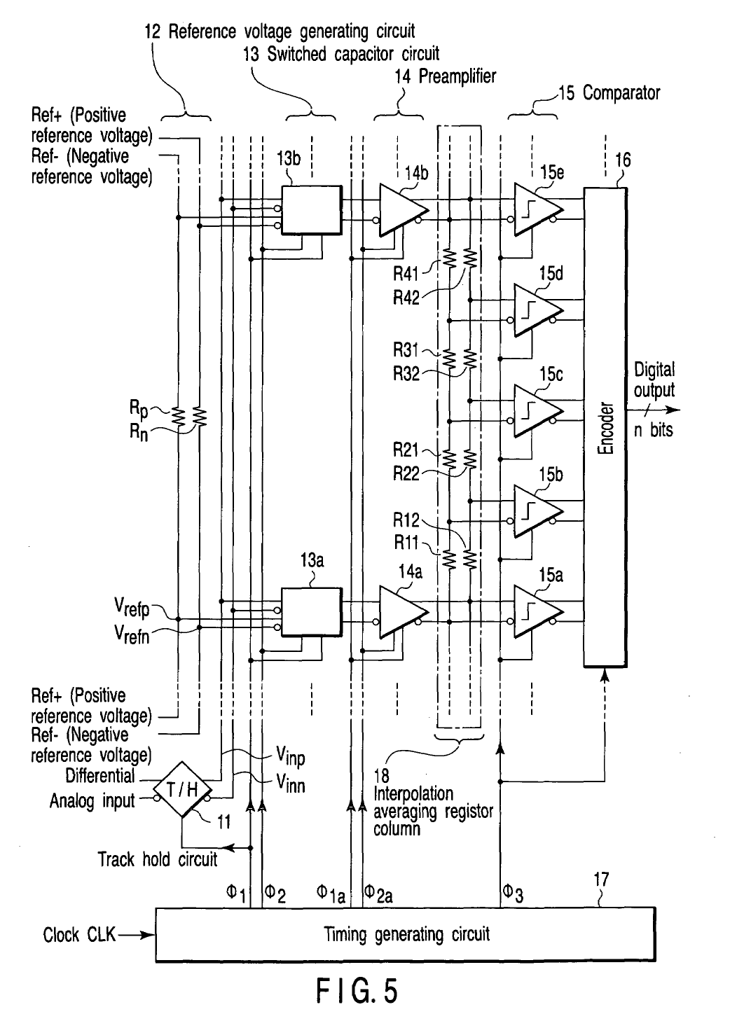

FIG. 5 is a diagram illustrating the configuration of a parallel A/D converter according to a second embodiment of the invention. This configuration has at least two sets (13a and 13b+14a and 14b) each of a combination of the switched capacitor circuit 13 and preamplifier 14 (13+14) and comparators 15 the number (for example, five; 15a to 15e) of which is larger than that of combinations of the switched capacitor circuit 13 and preamplifier 14. In this case, the reference voltage generating circuit 12 is configured to generate at least two different reference values (Rp, . . . and Rn, . . . into which Ref+ and Ref− have been divided). The two switched capacitor circuits 13a and 13b are configured to use the different reference values (Rp, . . . and Rn, . . . into which Ref+ and Ref− have been divided) from the reference voltage generating circuit 12 as the predetermined voltage values (Vrefp, Vrefn).

An interpolation/averaging resistor column 18 having at least one intermediate tap (in FIG. 5, three taps) is provided between outputs from the two preamplifiers 14a and 14b. The inputs to two (15a, 15e) of the five comparators 15a to 15e are connected to the outputs from the two preamplifiers 14a and 14b. The outputs from any of the comparators 15b to 15d are connected to the at least one intermediate tap of the interpolation averaging resistor column 18. The outputs from all the comparators 15a to 15e are provided to the encoder 16.

FIG. 5 illustrates a parallel A/D converter that uses the interpolation/averaging resistor column 18. The interpolation reduces the number of combinations of the switched capacitor circuit 13+preamplifier 14. This enables a further reduction in power consumption compared to the circuit configuration shown in FIG. 1. Further, the adjacent preamplifiers 14 are connected together via resistors. This enables the offset voltages in input equivalent Vos of the individual preamplifiers 14 to be averaged. Moreover, the reduced number of switched capacitor circuits 13 reduces the capacity load of the track hold circuit 11. This enables the track hold circuit 11 to operate at an increased speed.

### Effects of the Embodiment

1. Increased Speed

With the A/D converter including the configuration shown in FIG. 4, when φ1a is “High”, the sampling capacitance (Cs1, Cs2) may be recharged only by the amount corresponding to the variation in the charge amount caused by charge injection or clock feed-through. When φ2 is “High”, the load on the track hold circuit 11 is determined by the input capacity (small capacity) of the preamplifier 14. The skew in φ3 does not substantially affect the performance of the A/D converter. This enables the A/D converter to operate at an increased speed.

2. Reduced Power Consumption

With the A/D converter including the configuration shown in FIG. 4, the power consumption of the preamplifier (14) can be reduced by setting the pulse widths of φ1a and φ2a equal to the minimum required time (for normal digitization converting operations). A decrease in clock frequency reduces the duty cycles of φ1a and φ2a, thus more effectively reducing the power consumption.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An analog-to-digital converter comprising:
a track hold circuit which follows a variation in analog input value and which holds the analog input value at a predetermined timing, the track hold circuit outputting the analog input hold value;
a reference value generating circuit which generate predetermined reference values;
a switched capacitor circuit including a switch circuit which is switched on and off at a predetermined timing and a capacitor circuit which is charged at the predetermined timing under a first voltage corresponding to the predetermined reference values, the switched capacitor circuit holding a second voltage corresponding to a difference between the predetermined reference values or the first voltage and the analog input hold value;
a preamplifier which amplifies the second voltage held by the switched capacitance circuit to provide a preamplifier output and which has an input capacitance smaller than the capacity of the capacitor circuit;
a comparator which generates a logic level corresponding to the preamplifier output; and
an encoder which converts the logic level generated by the comparator into a binary code corresponding to the analog input value.

2. The analog-to-digital converter according to claim 1, further comprising a circuit which, if charges in the capacitor circuit charged under the first voltage vary, recharges the capacitor circuit by an amount corresponding to the variation.

3. The analog-to-digital converter according to claim 1, further comprising a timing generating circuit which generates first and second timing signals which set the predetermined timings with respect to a predetermined clock, the timing generating circuit being configured to generate the first and second timing signals and to generate a first pulse signal having a pulse width of a predetermined duration starting from a rear signal edge of the predetermined clock and a second pulse signal having a pulse width of a predetermined duration starting from a front signal edge of the predetermined clock,
wherein the analog input hold value includes first and second analog input hold values, the predetermined reference values include first and second reference values, and the preamplifier output includes first and second preamplifier outputs,
the capacitor circuits includes first and second capacitors, and the switch circuit includes a first switch which switches on and off a connection between one end of the first capacitor and the first reference value in accordance with the first timing signal, a second switch which switches on and off a connection between one end of the second capacitor and the second reference value in accordance with the first timing signal, a third switch which switches on and off a connection between one end of the first capacitor and the first analog input hold value in accordance with the second timing signal, and a fourth switch which switches on and off a connection between one end of the second capacitor and the second analog input hold value in accordance with the second timing signal, and
the preamplifier comprises a first transistor having a gate connected to the other end of the first capacitor, a drain providing the second preamplifier output, and a source, a second transistor having a gate connected to the other end of the second capacitor, a drain providing the first preamplifier output, and a source, a current source selectively connected to the sources of the first and second transistors, a fifth switch which switches on and off the gate and drain of the first transistor in accordance with the first pulse signal, a sixth switch which switches on and off the gate and drain of the second transistor in accordance with the first pulse signal, a seventh switch which switches on and off the current source and the source of each of the first and second transistors in accordance with the first pulse signal, and an eighth switch which switches on and off the current source and the source of each of the first and second transistors in accordance with the second pulse signal.

4. The analog-to-digital converter according to claim 3, which is configured so that if charges in the capacitor circuit charged under the first voltage vary, the seventh switch is turned on to recharge the capacitor circuit by an amount corresponding to the variation.

5. The analog-to-digital converter according to claim 1, wherein the track hold circuit is configured to output, as the analog input hold value, positive and negative analog hold input hold values corresponding to the analog input value,
the reference value generating circuit is configured to generate positive and negative reference values as the predetermined reference value,
the switched capacitor circuit is configured to hold, as the second voltage, a third difference between a first difference between the positive analog input hold value and the negative analog input hold value and a second difference between the positive reference value and the negative reference value,
the preamplifier comprises a differential amplifying circuit which amplifies the third difference to provide positive and negative preamplifier outputs as the preamplifier output, and
the comparator is configured to generate the logic level on the basis of a numerical comparison of the positive preamplifier output with the negative preamplifier output.

6. The analog-to-digital converter according to claim 2, wherein the track hold circuit is configured to output, as the analog input hold value, positive and negative analog hold input hold values corresponding to the analog input value,
the reference value generating circuit is configured to generate positive and negative reference values as the predetermined reference value,
the switched capacitor circuit is configured to hold, as the second voltage, a third difference between a first difference between the positive analog input hold value and the negative analog input hold value and a second difference between the positive reference value and the negative reference value,
the preamplifier comprises a differential amplifying circuit which amplifies the third difference to provide positive and negative preamplifier outputs as the preamplifier output, and
the comparator is configured to generate the logic level on the basis of a numerical comparison of the positive preamplifier output with the negative preamplifier output.

7. The analog-to-digital converter according to claim 3, wherein the track hold circuit is configured to output, as the analog input hold value, positive and negative analog hold input hold values corresponding to the analog input value,
the reference value generating circuit is configured to generate positive and negative reference values as the predetermined reference value,
the switched capacitor circuit is configured to hold, as the second voltage, a third difference between a first difference between the positive analog input hold value and the negative analog input hold value and a second difference between the positive reference value and the negative reference value,
the preamplifier comprises a differential amplifying circuit which amplifies the third difference to provide positive and negative preamplifier outputs as the preamplifier output, and
the comparator is configured to generate the logic level on the basis of a numerical comparison of the positive preamplifier output with the negative preamplifier output.

8. The analog-to-digital converter according to claim 4, wherein the track hold circuit is configured to output, as the analog input hold value, positive and negative analog hold input hold values corresponding to the analog input value,
the reference value generating circuit is configured to generate positive and negative reference values as the predetermined reference value,
the switched capacitor circuit is configured to hold, as the second voltage, a third difference between a first difference between the positive analog input hold value and the negative analog input hold value and a second difference between the positive reference value and the negative reference value,
the preamplifier comprises a differential amplifying circuit which amplifies the third difference to provide positive and negative preamplifier outputs as the preamplifier output, and
the comparator is configured to generate the logic level on the basis of a numerical comparison of the positive preamplifier output with the negative preamplifier output.

9. The analog-to-digital converter according to claim 1, wherein plural sets of the switched capacitor circuit, the preamplifier, and the comparator are provided,
the reference value generating circuit is configured to generate different reference values the number of which corresponds to that of the plural sets, and
the switched capacitor circuits in the plural sets are configured to use the different reference values from the reference value generating circuit, as the predetermined reference values.

10. The analog-to-digital converter according to claim 2, wherein plural sets of the switched capacitor circuit, the preamplifier, and the comparator are provided,
the reference value generating circuit is configured to generate different reference values the number of which corresponds to that of the plural sets, and
the switched capacitor circuits in the plural sets are configured to use the different reference values from the reference value generating circuit, as the predetermined reference values.

11. The analog-to-digital converter according to claim 3, wherein plural sets of the switched capacitor circuit, the preamplifier, and the comparator are provided,
the reference value generating circuit is configured to generate different reference values the number of which corresponds to that of the plural sets, and
the switched capacitor circuits in the plural sets are configured to use the different reference values from the reference value generating circuit, as the predetermined reference values.

12. The analog-to-digital converter according to claim 4, wherein plural sets of the switched capacitor circuit, the preamplifier, and the comparator are provided,
the reference value generating circuit is configured to generate different reference values the number of which corresponds to that of the plural sets, and
the switched capacitor circuits in the plural sets are configured to use the different reference values from the reference value generating circuit, as the predetermined reference values.

13. The analog-to-digital converter according to claim 5, wherein plural sets of the switched capacitor circuit, the preamplifier, and the comparator are provided,
the reference value generating circuit is configured to generate different reference values the number of which corresponds to that of the plural sets, and
the switched capacitor circuits in the plural sets are configured to use the different reference values from the reference value generating circuit, as the predetermined reference values.

14. The analog-to-digital converter according to claim 8, wherein plural sets of the switched capacitor circuit, the preamplifier, and the comparator are provided,
the reference value generating circuit is configured to generate different reference values the number of which corresponds to that of the plural sets, and
the switched capacitor circuits in the plural sets are configured to use the different reference values from the reference value generating circuit, as the predetermined reference values.

15. The analog-to-digital converter according to claim 1, wherein at least two sets of the switched capacitor circuit and the preamplifier are present, and the number of comparators is larger than that of combinations of the switched capacitor circuit and the preamplifier,
the reference value generating circuit is configured to generate at least two different reference values,
two of the switched capacitor circuits are configured to use the different reference values from the reference value generating circuit, as the predetermined reference values,
an interpolation/averaging resistor column having at least one intermediate tap is provided between two of the preamplifiers, and
inputs to two of the comparators are connected to outputs from two of the preamplifiers, and an input to any comparator which is different from the two comparators is connected to the at least one intermediate tap is provided between two of the preamplifiers, and the outputs from all the comparators are provided to the encoder.

16. The analog-to-digital converter according to claim 2, wherein at least two sets of the switched capacitor circuit and the preamplifier are present, and the number of comparators is larger than that of combinations of the switched capacitor circuit and the preamplifier,
the reference value generating circuit is configured to generate at least two different reference values,
two of the switched capacitor circuits are configured to use the different reference values from the reference value generating circuit, as the predetermined reference values,
an interpolation/averaging resistor column having at least one intermediate tap is provided between two of the preamplifiers, and
inputs to two of the comparators are connected to outputs from two of the preamplifiers, and an input to any comparator which is different from the two comparators is connected to the at least one intermediate tap is provided between two of the preamplifiers, and the outputs from all the comparators are provided to the encoder.

17. The analog-to-digital converter according to claim 3, wherein at least two sets of the switched capacitor circuit and the preamplifier are present, and the number of comparators is larger than that of combinations of the switched capacitor circuit and the preamplifier,
the reference value generating circuit is configured to generate at least two different reference values,
two of the switched capacitor circuits are configured to use the different reference values from the reference value generating circuit, as the predetermined reference values,
an interpolation/averaging resistor column having at least one intermediate tap is provided between two of the preamplifiers, and
inputs to two of the comparators are connected to outputs from two of the preamplifiers, and an input to any comparator which is different from the two comparators is connected to the at least one intermediate tap is provided between two of the preamplifiers, and the outputs from all the comparators are provided to the encoder.

18. The analog-to-digital converter according to claim 4, wherein at least two sets of the switched capacitor circuit and the preamplifier are present, and the number of comparators is larger than that of combinations of the switched capacitor circuit and the preamplifier,
the reference value generating circuit is configured to generate at least two different reference values,
two of the switched capacitor circuits are configured to use the different reference values from the reference value generating circuit, as the predetermined reference values,
an interpolation/averaging resistor column having at least one intermediate tap is provided between two of the preamplifiers, and
inputs to two of the comparators are connected to outputs from two of the preamplifiers, and an input to any comparator which is different from the two comparators is connected to the at least one intermediate tap is provided between two of the preamplifiers, and the outputs from all the comparators are provided to the encoder.

19. The analog-to-digital converter according to claim 13, wherein at least two sets of the switched capacitor circuit and the preamplifier are present, and the number of comparators is larger than that of combinations of the switched capacitor circuit and the preamplifier,
the reference value generating circuit is configured to generate at least two different reference values,
two of the switched capacitor circuits are configured to use the different reference values from the reference value generating circuit, as the predetermined reference values,
an interpolation/averaging resistor column having at least one intermediate tap is provided between two of the preamplifiers, and
inputs to two of the comparators are connected to outputs from two of the preamplifiers, and an input to any comparator which is different from the two comparators is connected to the at least one intermediate tap is provided between two of the preamplifiers, and the outputs from all the comparators are provided to the encoder.

20. The analog-to-digital converter according to claim 14, wherein at least two sets of the switched capacitor circuit and the preamplifier are present, and the number of comparators is larger than that of combinations of the switched capacitor circuit and the preamplifier,
the reference value generating circuit is configured to generate at least two different reference values,
two of the switched capacitor circuits are configured to use the different reference values from the reference value generating circuit, as the predetermined reference values,
an interpolation/averaging resistor column having at least one intermediate tap is provided between two of the preamplifiers, and
inputs to two of the comparators are connected to outputs from two of the preamplifiers, and an input to any comparator which is different from the two comparators is connected to the at least one intermediate tap is provided between two of the preamplifiers, and the outputs from all the comparators are provided to the encoder.
